(19) United States
(12) Patent Application Publication
(10) Pub. No.: US 2026/0305290 A1
(43) Pub. Date: Oct. 1, 2026

(54) SEMICONDUCTOR DEVICE

(71) Applicant: Renesas Electronics Corporation, Tokyo (JP)

(72) Inventor: Eiji HIRAIWA, Tokyo (JP)

(21) Appl. No.: 19/462,242

(22) Filed: Jan. 28, 2026

(30) Foreign Application Priority Data
Mar. 26, 2025 (JP) 2025-052193

(51) Int. Cl. H10W 20/20; H10D 1/68

(52) U.S. Cl. CPC H10W 20/222; H10D 1/68

(57) ABSTRACT

A semiconductor device includes a first interlayer insulating film, a lower electrode formed on the first interlayer insulating film, a dielectric film formed on the lower electrode, an upper electrode formed on the dielectric film, and at least one conductive layer formed in the first interlayer insulating film so as to contact the lower electrode.

### CROSS-REFERENCE TO RELATED APPLICATIONS

The disclosure of Japanese Patent Application No. 2025-052193 filed on Mar. 26, 2025, including the specification, drawings and abstract is incorporated herein by reference in its entirety.

### BACKGROUND

This disclosure relates to a semiconductor device.

There are disclosed techniques listed below.

[Patent Document 1] Japanese Unexamined Patent Application Publication No. 2009-130207

Patent Document 1 discloses a semiconductor device having an interlayer insulating film, a cap film, a lower electrode, a dielectric film, and an upper electrode. The cap film is formed on the interlayer insulating film. The lower electrode is formed on the cap film. The dielectric film is formed on the lower electrode, and the upper electrode is formed on the dielectric film. The lower electrode, the dielectric film, and the upper electrode configure a MIM (Metal Insulator Metal) capacitor.

### SUMMARY

In the semiconductor device disclosed in Patent Document 1, a plurality of masks are required to form the MIM capacitor. Other problems and novel features will become apparent from the description herein and from the accompanying drawings.

The semiconductor device of this disclosure includes a first interlayer insulating film, a lower electrode formed on the first interlayer insulating film, a dielectric film formed on the lower electrode, an upper electrode formed on the dielectric film, and at least one conductive layer formed in the first interlayer insulating film so as to contact the lower electrode.

According to the semiconductor device of this disclosure, the manufacturing step of the MIM capacitor can be simplified.

### BRIEF DESCRIPTION OF THE DRAWINGS

FIG. 1 is a plan view of a semiconductor device DEV1.

FIG. 2 is a cross-sectional view of the semiconductor device DEV1 at II-II of FIG. 1.

FIG. 3 is a manufacturing step diagram of the semiconductor device DEV1.

FIG. 4 is a cross-sectional view explaining a preparation step S1 in a manufacturing method of the semiconductor device DEV1.

FIG. 5 is a cross-sectional view explaining a capacitor formation step S2 in the manufacturing method of the semiconductor device DEV1.

FIG. 6 is a cross-sectional view explaining an interlayer insulating film formation step S3 in the manufacturing method of the semiconductor device DEV1.

FIG. 7 is a cross-sectional view of a semiconductor device DEV7.

FIG. 8 is a cross-sectional view of a semiconductor device DEV2.

FIG. 9A is a first cross-sectional view explaining a capacitor formation step S2 in a manufacturing method of the semiconductor device DEV2.

FIG. 9B is a second cross-sectional view explaining the capacitor formation step S2 in the manufacturing method of the semiconductor device DEV2.

FIG. 9C is the third cross-sectional view explaining the capacitor formation step S2 in the manufacturing method of the semiconductor device DEV2.

FIG. 10 is a cross-sectional view of a semiconductor device DEV3.

FIG. 11 is a manufacturing step diagram of the semiconductor device DEV3.

FIG. 12 is a cross-sectional view explaining a preparation step S5 in the manufacturing method of the semiconductor device DEV3.

FIG. 13 is a cross-sectional view explaining an interlayer insulating film formation step S6 in the manufacturing method of the semiconductor device DEV3.

FIG. 14 is a cross-sectional view explaining a via plug formation step S7 in the manufacturing method of the semiconductor device DEV3.

FIG. 15 is a cross-sectional view explaining a capacitor formation step S8 in the manufacturing method of the semiconductor device DEV3.

FIG. 16 is a cross-sectional view of a semiconductor device DEV8.

FIG. 17 is a partially enlarged cross-sectional view of a semiconductor device DEV4.

FIG. 18 is a cross-sectional view of a semiconductor device DEV5.

FIG. 19A is a first cross-sectional view explaining a capacitor formation step S8 in the manufacturing method of the semiconductor device DEV4.

FIG. 19B is a second cross-sectional view explaining the capacitor formation step S8 in the manufacturing method of the semiconductor device DEV4.

FIG. 19C is a third cross-sectional view explaining the capacitor formation step S8 in the manufacturing method of the semiconductor device DEV4.

FIG. 19D is a fourth cross-sectional view explaining the capacitor formation step S8 in the manufacturing method of the semiconductor device DEV4.

FIG. 20 is a partially enlarged cross-sectional view of a semiconductor device DEV6.

### DETAILED DESCRIPTION

The details of the embodiments of this disclosure will be described with reference to the drawings. In the following drawings, the same reference numerals are assigned to the same or corresponding parts, and redundant descriptions are not repeated.

### First Embodiment

The semiconductor device DEV1 according to the first embodiment will be described.

### Structure of Semiconductor Device DEV1

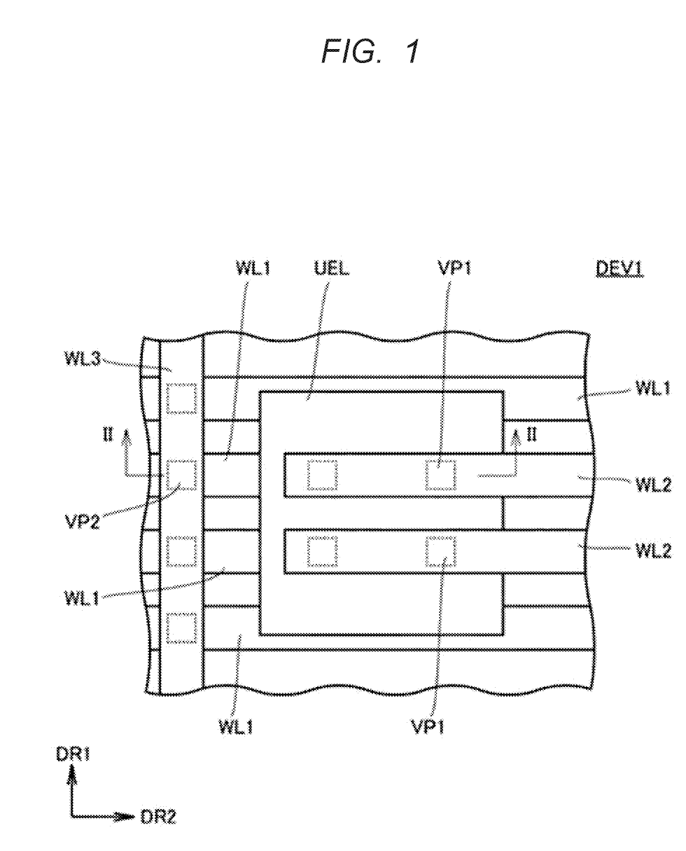

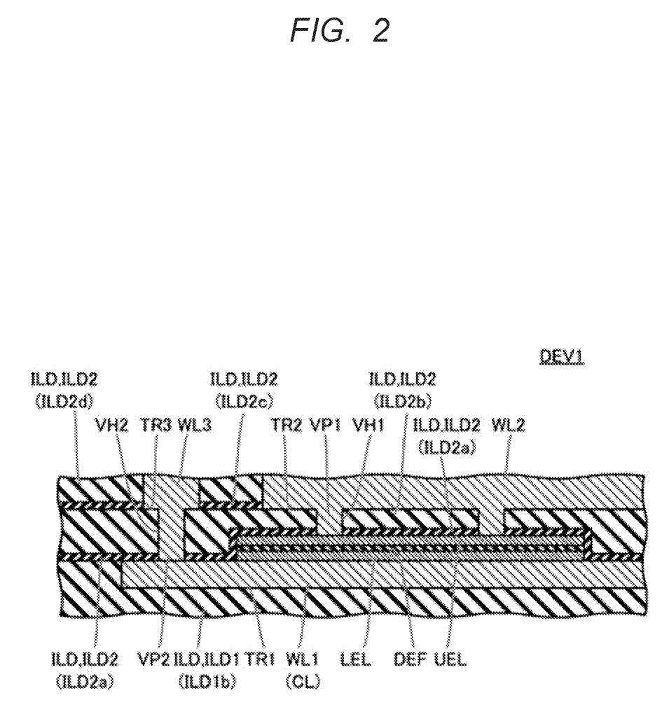

As shown in FIGS. 1 and 2, the semiconductor device DEV1 includes a plurality of interlayer insulating films ILD. The plurality of interlayer insulating films ILD are laminated on a semiconductor substrate not shown. The semiconductor device DEV1 further includes a lower electrode LEL, a dielectric film DEF, and an upper electrode UEL. The lower electrode LEL is formed on the interlayer insulating film ILD1 among the plurality of interlayer insulating films ILD. The interlayer insulating film ILD1 includes a first layer ILD1a (not shown) and a second layer ILD1b formed on the first layer ILD1a. The first layer ILD1a is formed of silicon carbonitride, for example, and the second layer ILD1b is formed of silicon oxide. The dielectric film DEF is formed on the lower electrode LEL, and the upper electrode UEL is formed on the dielectric film DEF. The lower electrode LEL, the dielectric film DEF, and the upper electrode UEL configure a MIM capacitor. The lower electrode LEL and the upper electrode UEL are formed of titanium nitride, for example. The dielectric film DEF is formed of silicon nitride, for example.

The semiconductor device DEV1 further includes a plurality of conductive layers CL. The conductive layer CL is formed in the interlayer insulating film ILD1 so as to contact the lower electrode LEL. More specifically, a plurality of trenches TR1 are formed at the upper surface of the interlayer insulating film ILD1, and the plurality of conductive layers CL are formed in the trenches TR1. In the first embodiment, the plurality of conductive layers CL are a plurality of wirings WL1. The wiring WL1 is formed of copper or copper alloy, for example. In the example shown in FIGS. 1 and 2, the number of conductive layers CL (wiring WL1) and the number of trenches TR1 are two or more, but the number of conductive layers CL (wiring WL1) and the number of trenches TR1 may be one.

In plan view, the plurality of wirings WL1 are arranged in a first direction DR1 with a distance between two of the plurality of wirings WL1 adjacent to each other. The wiring WL1 extends in a second direction DR2 perpendicular to the first direction DR1 in plan view. In plan view, the lower electrode LEL, the dielectric film DEF, and the upper electrode UEL overlap the plurality of wirings WL1.

The interlayer insulating film ILD2 among the plurality of interlayer insulating films ILD is formed on the interlayer insulating film ILD1 so as to cover the lower electrode LEL, the dielectric film DEF, and the upper electrode UEL. The trench TR2 and the trench TR3 are formed at the upper surface of the interlayer insulating film ILD2. A via hole VH1 is formed at the bottom surface of the trench TR2. A via hole VH2 is formed at the bottom surface of the trench TR3.

The interlayer insulating film ILD2 includes a first layer ILD2a, a second layer ILD2b, a third layer ILD2c, and a fourth layer ILD2d. The second layer ILD2b is formed on the first layer ILD2a. The third layer ILD2c is formed on the second layer ILD2b. The fourth layer ILD2d is formed on the third layer ILD2c. The first layer ILD2a and the third layer ILD2c are formed of silicon carbonitride, for example. The second layer ILD2b and the fourth layer ILD2d are formed of silicon oxide, for example.

The semiconductor device DEV1 further includes a wiring WL2, a wiring WL3, a via plug VP1, and a via plug VP2. The wiring WL2 is formed in the trench TR2, and the wiring WL3 is formed in the trench TR3. The via plug VP1 is formed in the via hole VH1, and the via plug VP2 is formed in the via hole VH2. The via plug VP1 is integrally formed with the wiring WL2, and the via plug VP2 is integrally formed with the wiring WL3. The via plug VP1 electrically connects the upper electrode UEL and the wiring WL2. The via plug VP2 electrically connects the wiring WL1 (conductive layer CL) and the wiring WL3. The wiring WL2, the wiring WL3, the via plug VP1, and the via plug VP2 are formed of copper or copper alloy, for example.

### Manufacturing Method of Semiconductor Device DEV2

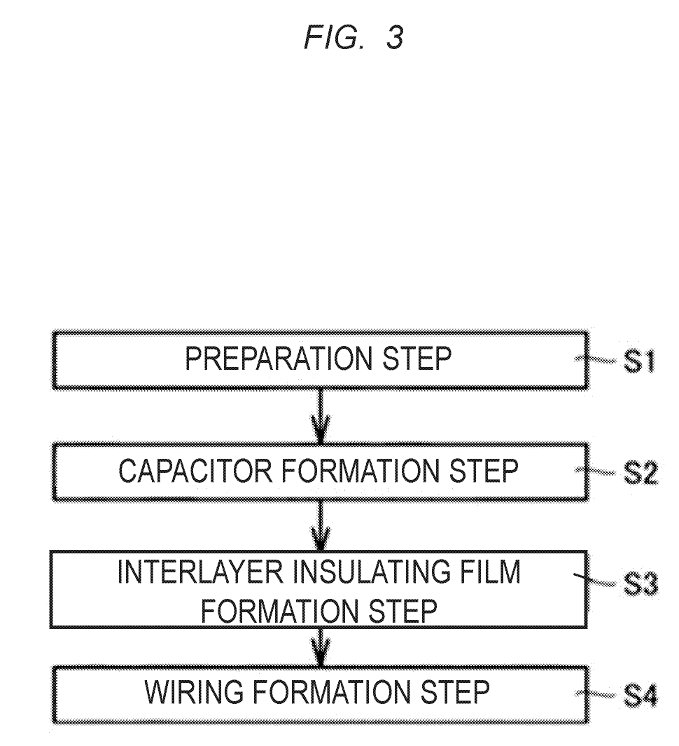

As shown in FIG. 3, the manufacturing method of the semiconductor device DEV1 includes a preparation step S1, a capacitor formation step S2, an interlayer insulating film formation step S3, and a wiring formation step S4.

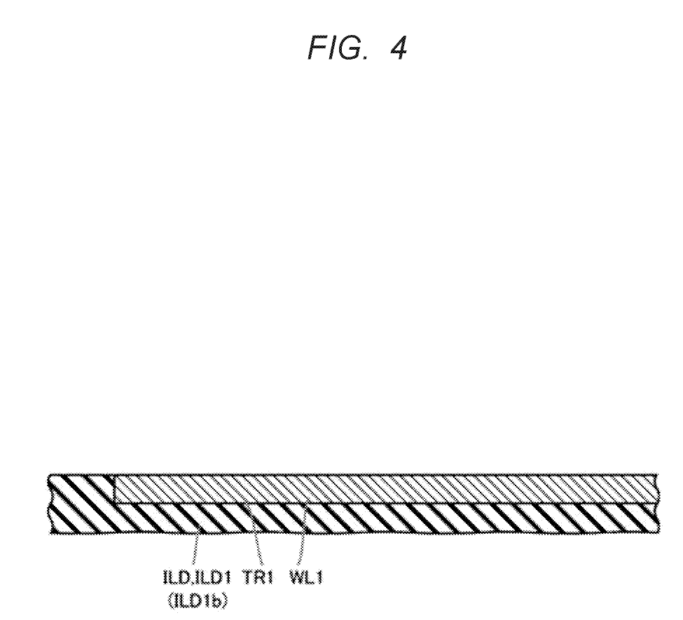

As shown in FIG. 4, in the preparation step S1, a semiconductor substrate with at least one interlayer insulating film ILD formed on the semiconductor substrate is prepared. If a plurality of interlayer insulating films ILD are formed at this stage, the top layer among the plurality of interlayer insulating films ILD is the interlayer insulating film ILD1. Also, at this stage, the wiring WL1 (conductive layer CL) is formed in the interlayer insulating film ILD1. After the preparation step S1, the capacitor formation step S2 is performed.

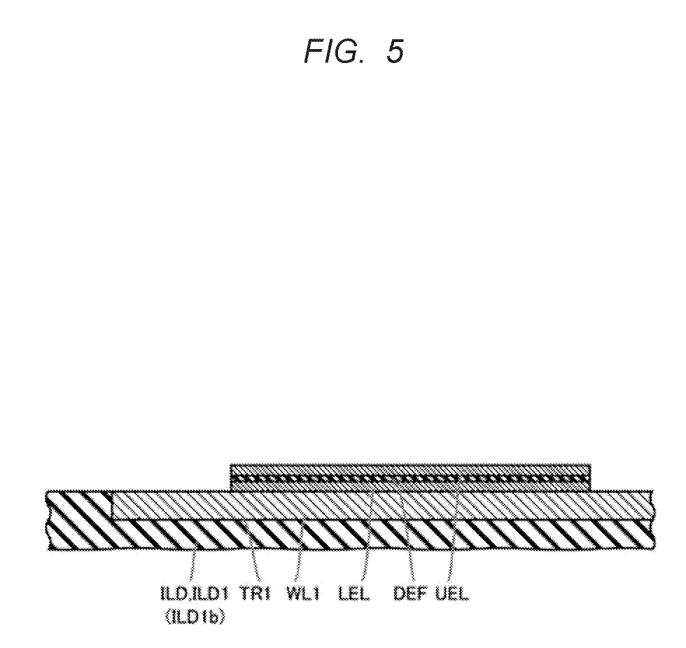

As shown in FIG. 5, in the capacitor formation step S2, a capacitor formed of the lower electrode LEL, the dielectric film DEF, and the upper electrode UEL is formed on the interlayer insulating film ILD1. In the capacitor formation step S2, firstly, the constituent materials of the lower electrode LEL, the dielectric film DEF, and the upper electrode UEL are sequentially formed on the interlayer insulating film ILD1. The constituent materials of the lower electrode LEL and the upper electrode UEL are formed, for example, by sputtering, and the constituent material of the dielectric film DEF is formed, for example, by the CVD (Chemical Vapor Deposition) method. Secondly, a resist pattern is formed on the constituent material of the upper electrode UEL. Thirdly, using the resist pattern as a mask, dry etching is performed on the constituent materials of the lower electrode LEL, the dielectric film DEF, and the upper electrode UEL. Through the above steps, the lower electrode LEL, the dielectric film DEF, and the upper electrode UEL are formed.

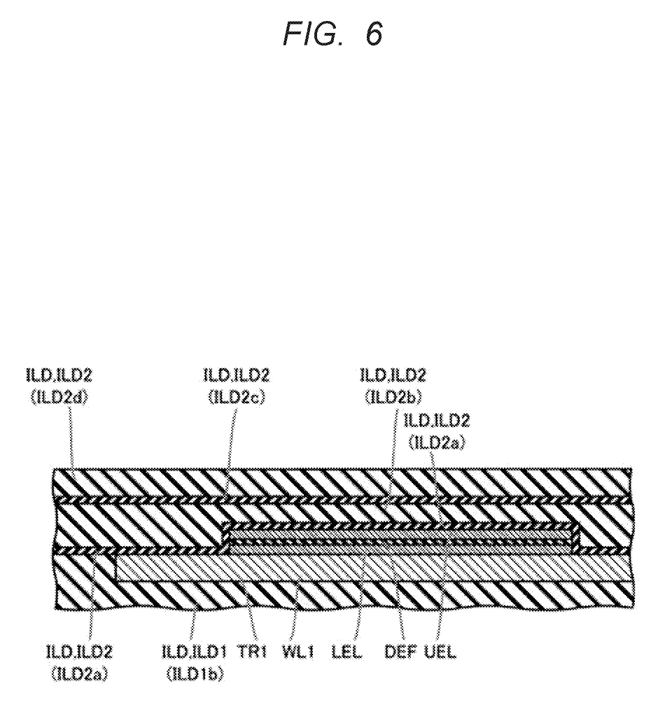

As shown in FIG. 6, in the interlayer insulating film formation step S3, the interlayer insulating film ILD2 is formed on the interlayer insulating film ILD1 so as to cover the lower electrode LEL, the dielectric film DEF, and the upper electrode UEL. In the interlayer insulating film formation step S3, firstly, for example, by the CVD method, the constituent material of the first layer ILD2a and the constituent material of the second layer ILD2b are sequentially formed. Secondly, for example, by the CMP (Chemical Mechanical Polishing) method, the upper surface of the second layer ILD2b is planarized. Thirdly, for example, by the CVD method, the third layer ILD2c and the fourth layer ILD2d are sequentially formed. Through the above, the interlayer insulating film ILD2 is formed.

In the wiring formation step S4, the wiring WL2, the wiring WL3, the via plug VP1, and the via plug VP2 are formed in the interlayer insulating film ILD2. In the wiring formation step S4, firstly, a first resist pattern is formed on the interlayer insulating film ILD2. Secondly, by performing dry etching on the interlayer insulating film ILD2 using the first resist pattern as a mask, the via hole VH1 and the via hole VH2 are formed in the interlayer insulating film ILD2. Thirdly, a second resist pattern, different from the first resist pattern, is formed. Fourthly, by performing dry etching on the interlayer insulating film ILD2 using the second resist pattern as a mask, the trench TR2 and the trench TR3 are formed in the interlayer insulating film ILD2.

Fifthly, for example, by sputtering, a barrier metal and a seed layer, not shown, are sequentially formed. The barrier layer and the seed metal are formed on the inner wall surfaces of via hole VH1, on the inner wall surfaces of via hole VH2, on the wiring WL1 exposed from the via hole VH1, and on the wiring WL1 exposed from the via hole VH2. Additionally, the barrier metal and the seed layer are also formed on the bottom surface of the trench TR2, on the inner wall surface of the trench TR2, on the bottom surface of the trench TR3, on the inner wall surface of the trench TR2, and on the interlayer insulating film ILD2. The barrier metal is formed of titanium nitride, for example, and the seed metal is formed of copper or copper alloy, for example.

Sixthly, for example, by electroplating, constituent materials such as the wiring WL2 are formed on the seed layer. Seventhly, for example, by the CMP method, constituent materials such as the wiring WL2 formed outside the trench TR1, outside the trench TR2, outside the via hole VH1, and outside the via hole VH2 are removed. At this time, the seed layer and the barrier metal formed on the interlayer insulating film ILD2 are also removed. As described above, the wiring WL2, the wiring WL3, the via plug VP1, and the via plug VP2 are formed by the dual damascene method, and the structure of the semiconductor device DEV1 shown in FIGS. 1 and 2 is formed.

### Effects of Semiconductor Device DEV1

In the manufacturing method of the semiconductor device DEV1, the constituent materials of the lower electrode LEL, the dielectric film DEF, and the upper electrode UEL are sequentially formed. Subsequently, by collectively patterning the constituent materials of the lower electrode LEL, the dielectric film DEF, and the upper electrode UEL, the lower electrode LEL, the dielectric film DEF, and the upper electrode UEL are formed. Therefore, according to the semiconductor device DEV1, an MIM capacitor can be formed by using a single mask, that is, a mask for forming the resist pattern used in the capacitor formation step S2.

When a single trench TR1 is formed at the upper surface of the interlayer insulating film ILD1, during the CMP method performed to remove the constituent materials of the trench TR1 formed outside the trench TR1, the upper surface of the wiring WL1 may become recessed due to dishing. On the other hand, when a plurality of trenches TR1 are formed at the upper surface of the interlayer insulating film ILD1, the width in the first direction DR1 of each of the plurality of trenches TR1 can be made smaller compared to forming the single trench TR1, thus suppressing the occurrence of dishing on the upper surface of the wiring WL1.

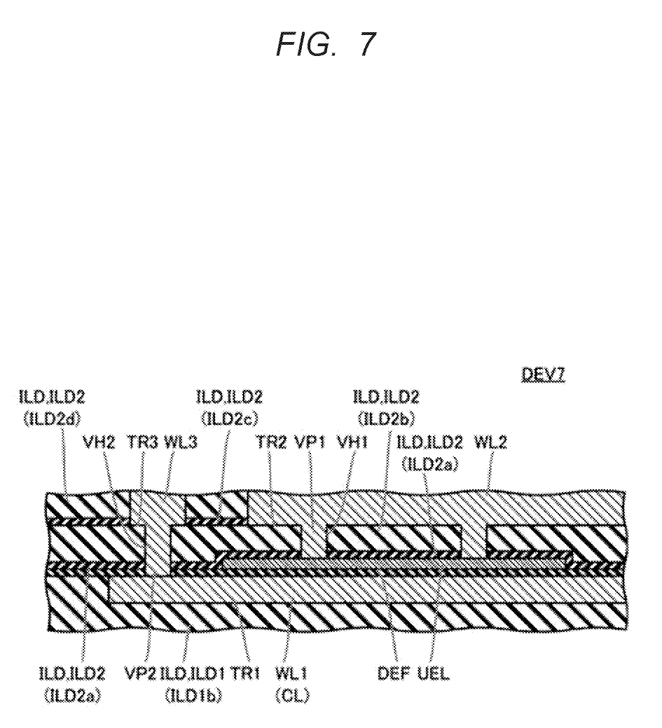

As shown in FIG. 7, the semiconductor device DEV7 according to the comparative example does not have a lower electrode LEL. In the semiconductor device DEV7, the wiring WL1 functions as the lower electrode of the MIM capacitor. In the semiconductor device DEV7, the dielectric film DEF is formed on the wiring WL1 and on the interlayer insulating film ILD1. The semiconductor device DEV7 can form an MIM capacitor using a single mask. However, since the wiring WL1 is formed of copper or copper alloy and not of high melting point metals such as titanium nitride, voids may occur in the lower electrode (wiring WL1) due to electromigration or stress migration, causing changes in the capacitance of the MIM capacitor. On the other hand, in the semiconductor device DEV1, since the lower electrode LEL is formed of high melting point metals such as titanium nitride, changes in the capacitance of the MIM capacitor due to electromigration or stress migration are suppressed.

### Second Embodiment

The semiconductor device DEV2 according to the second embodiment will be described. Here, the differences from the semiconductor device DEV1 will be mainly described, and repetitive explanations will not be repeated.

### Structure of Semiconductor Device DEV2

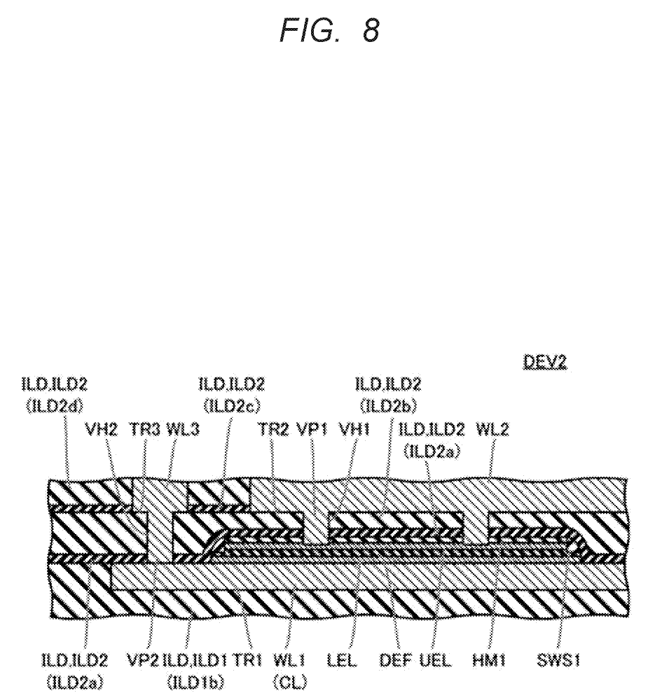

As shown in FIG. 8, in the semiconductor device DEV2, the lower electrode LEL and the dielectric film DEF protrude from both side surfaces of the upper electrode UEL in cross-sectional view. The semiconductor device DEV2 has a hard mask HM1 and a sidewall spacer SWS1. The hard mask HM1 is formed on the upper electrode UEL. The sidewall spacer SWS1 is formed on the dielectric film DEF so as to contact both side surfaces of the upper electrode UEL. The hard mask HM1 is formed of silicon oxide, for example, and the sidewall spacer SWS1 is formed of silicon oxide, for example.

### Manufacturing Method of Semiconductor Device DEV2

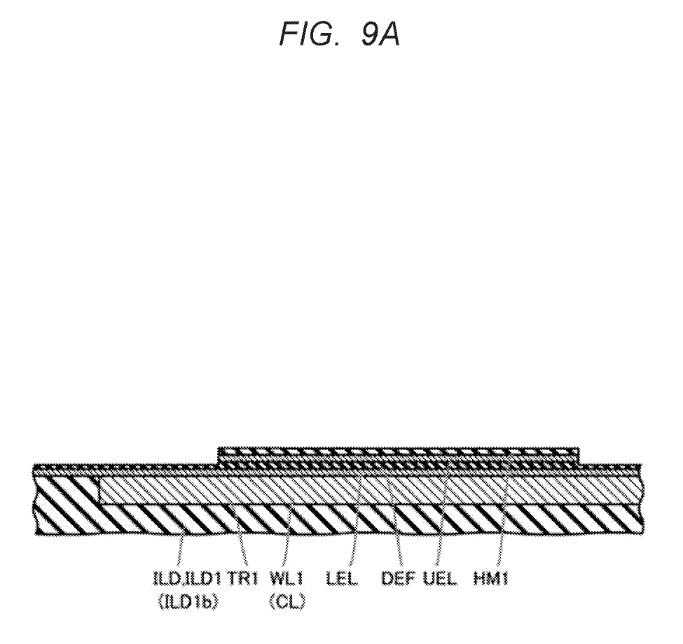

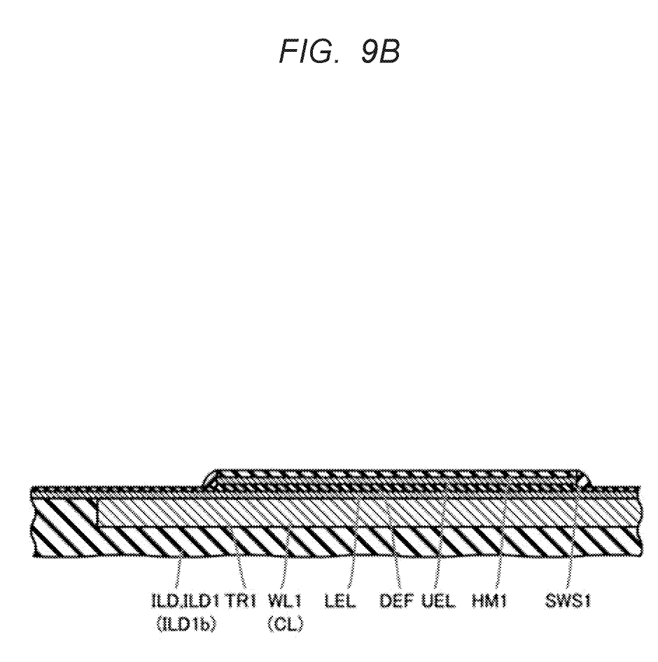

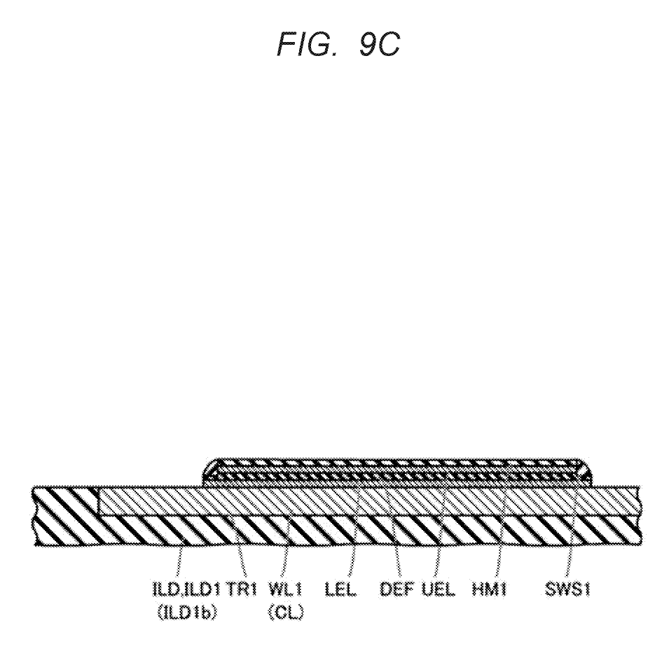

In the manufacturing method of the semiconductor device DEV2, the hard mask HM1 and the sidewall spacer SWS1 are further formed in the capacitor formation step S2. As shown in FIG. 9A, in the capacitor formation step S2 of the manufacturing method of the semiconductor device DEV2, firstly, the constituent materials of the lower electrode LEL, the dielectric film DEF, and the upper electrode UEL are sequentially formed on the interlayer insulating film ILD1. Secondly, for example, by the CVD method, the constituent material of the hard mask HM1 is formed on the constituent material of the upper electrode UEL. Thirdly, a resist pattern is formed on the constituent material of the hard mask HM1. Fourthly, by performing dry etching on the constituent material of the hard mask HM1 using the resist pattern as a mask, the hard mask HM1 is formed. Fifthly, dry etching is performed on the constituent material of the upper electrode UEL using the hard mask HM1 as a mask. Sixthly, for example, by the CVD method, the constituent material of the sidewall spacer SWS1 is formed on the dielectric film DEF so as to cover the upper electrode UEL and the hard mask HM1.

In the capacitor formation step S2 of the manufacturing method of the semiconductor device DEV2, as shown in FIG. 9B, seventhly, etch-back is performed on the constituent material of the sidewall spacer SWS1. As shown in FIG. 9C, in the capacitor formation step S2 of the manufacturing method of the semiconductor device DEV2, eighthly, dry etching is performed on the constituent materials of the dielectric film DEF and the lower electrode LEL using the sidewall spacer SWS1 and the hard mask HM1 as masks. Thus, in the capacitor formation step S2 of the manufacturing method of the semiconductor device DEV2, in addition to the lower electrode LEL, the dielectric film DEF, and the upper electrode UEL, the hard mask HM1 and the sidewall spacer SWS1 are formed.

### Effects of Semiconductor Device DEV2

In the semiconductor device DEV1, dry etching is collectively performed on the constituent materials of the lower electrode LEL, the dielectric film DEF, and the upper electrode UEL. Therefore, the side surface of the dielectric film DEF is continuous with the side surfaces of the lower electrode LEL and the upper electrode UEL, shortening the extension distance between the side surfaces of the lower electrode LEL and the upper electrode UEL. Additionally, during dry etching, the constituent material of the upper electrode UEL may adhere to the side surface of the dielectric film DEF. Therefore, in the MIM capacitor of the semiconductor device DEV1, leak current may flow between the lower electrode LEL and the upper electrode UEL through the side surface of the dielectric film DEF.

On the other hand, in the semiconductor device DEV2, the dielectric film DEF protrudes from both side surfaces of the upper electrode UEL. Additionally, in the semiconductor device DEV2, the side surface of the dielectric film DEF is formed after the upper electrode UEL is formed. Therefore, in the semiconductor device DEV2, compared to the semiconductor device DEV1, the extension distance between the side surfaces of the lower electrode LEL and the upper electrode UEL is longer, and the constituent material of the upper electrode UEL is less likely to adhere to the side surface of the dielectric film DEF. Thus, according to the semiconductor device DEV2, the flow of leak current between the lower electrode LEL and the upper electrode UEL through the side surface of the dielectric film DEF is suppressed. Note that, in the manufacturing method of the semiconductor device DEV2, a single mask is used in the capacitor formation step S2, allowing the manufacturing step of the MIM capacitor to be simplified.

### Third Embodiment

The semiconductor device DEV3 according to the third embodiment will be described.

### Structure of Semiconductor Device DEV3

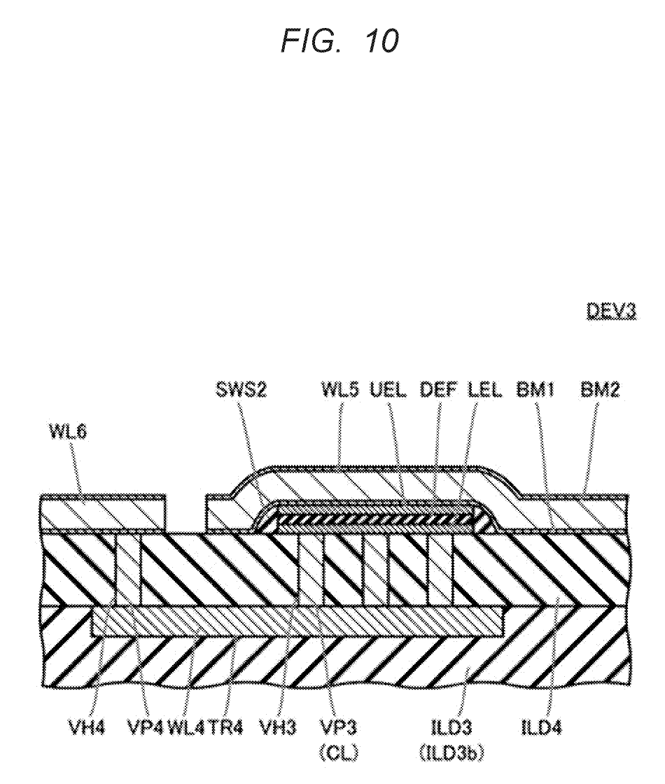

As shown in FIG. 10, in the semiconductor device DEV3, the interlayer insulating film ILD4, which is located at the top layer among the plurality of interlayer insulating films ILD, is formed on the interlayer insulating film ILD3 among the plurality of interlayer insulating films ILD. The interlayer insulating film ILD3 has a first layer ILD3a, not shown, and a second layer ILD3b formed on the first layer ILD3a. A trench TR4 is formed at the upper surface of the interlayer insulating film ILD3. The first layer ILD3a is formed of, for example, silicon carbonitride. The second layer ILD3b is formed of, for example, silicon oxide. The interlayer insulating film ILD4 is formed of, for example, silicon oxide. The semiconductor device DEV3 further includes a wiring WL4. The wiring WL4 is formed in the trench TR4. The wiring WL4 is formed of, for example, copper or a copper alloy.

In the interlayer insulating film ILD4, a plurality of via plugs VP3 are formed as a plurality of conductive layers CL. However, the number of via plugs VP3 may be one. In the semiconductor device DEV3, the lower electrode LEL is formed on the interlayer insulating film ILD4 and contacts a plurality of via plugs VP3. More specifically, the via holes VH3 are formed in the interlayer insulating film ILD3, and the via plugs VP3 are formed in the via holes VH3. The semiconductor device DEV3 further includes a via plug VP4. The via plug VP4 is formed in the interlayer insulating film ILD4. More specifically, the via hole VH4 is formed in the interlayer insulating film ILD4, and the via plug VP4 is formed in the via hole VH4. The via plugs VP3, VP4 are electrically connected to the wiring WL4. The via plugs VP3, VP4 are formed of, for example, tungsten.

The semiconductor device DEV3 further includes a sidewall spacer SWS2. The sidewall spacer SWS2 is formed on the interlayer insulating film ILD4 so as to contact both side surfaces of the lower electrode LEL, both side surfaces of the dielectric film DEF, and both side surfaces of the upper electrode UEL. The sidewall spacer SWS2 is formed of, for example, silicon oxide. The semiconductor device DEV3 further includes a wiring WL5 and a wiring WL6. The wiring WL5 is formed on the interlayer insulating film ILD4 so as to cover the upper electrode UEL and the sidewall spacer SWS2. The wiring WL5 is electrically connected to the upper electrode UEL but is electrically insulated from the lower electrode LEL by the sidewall spacer SWS2. The wiring WL6 is formed on the interlayer insulating film ILD4 and is electrically connected to the via plug VP4. The wiring WL5 and the wiring WL6 are formed of, for example, aluminum or an aluminum alloy.

The semiconductor device DEV3 may further include a barrier metal BM1 and a berrier metal BM2. The barrier metal BM1 is formed between the wiring WL5 and the interlayer insulating film ILD4 and between the wiring WL6 and the interlayer insulating film ILD4. The barrier metal BM2 is formed on the wiring WL5 and the wiring WL6. The barrier metal BM1 and the barrier metal BM2 are formed of, for example, titanium nitride.

### Manufacturing Method of Semiconductor Device DEV3

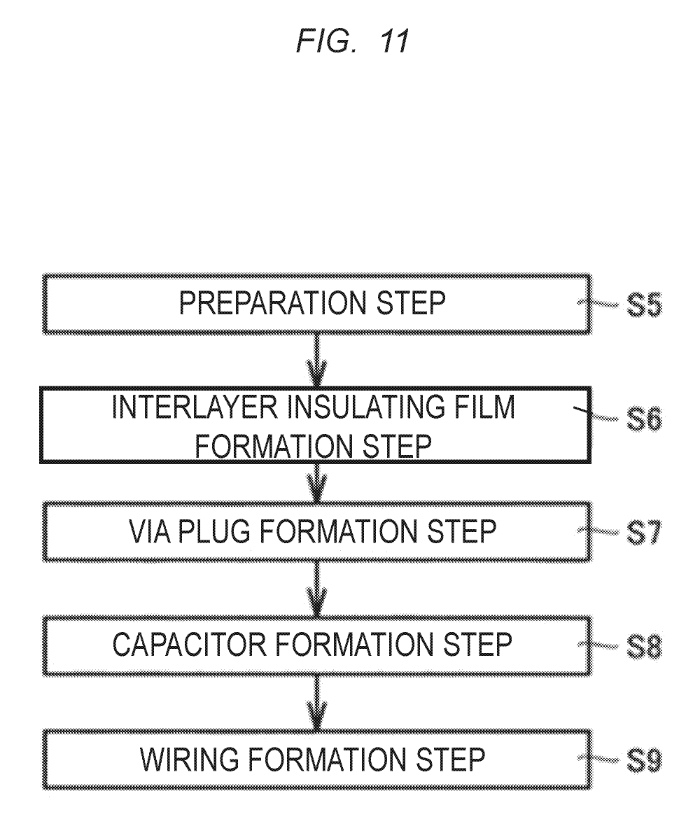

As shown in FIG. 11, the manufacturing method of the semiconductor device DEV3 includes a preparation step S5, an interlayer insulating film formation step S6, a via plug formation step S7, a capacitor formation step S8, and a wiring formation step S9. The interlayer insulating film formation step S6 is performed after the preparation step S5, and the via plug formation step S7 is performed after the interlayer insulating film formation step S6. The capacitor formation step S8 is performed after the via plug formation step S7, and the wiring formation step S9 is performed after the capacitor formation step S8.

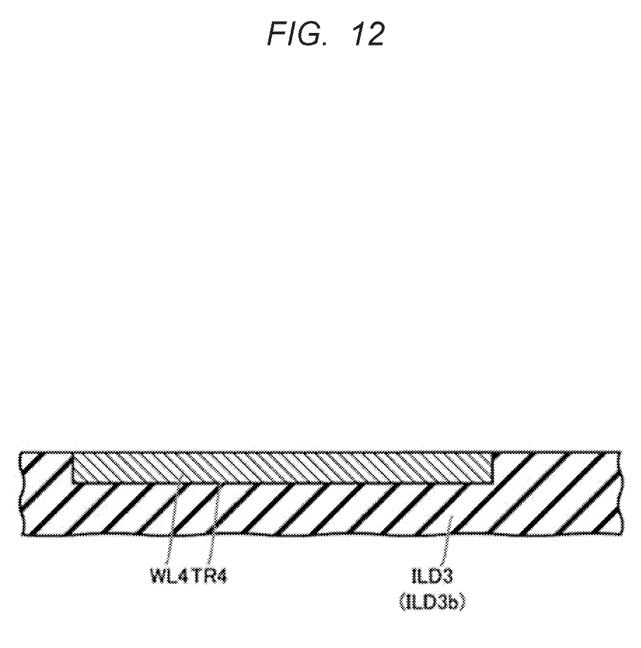

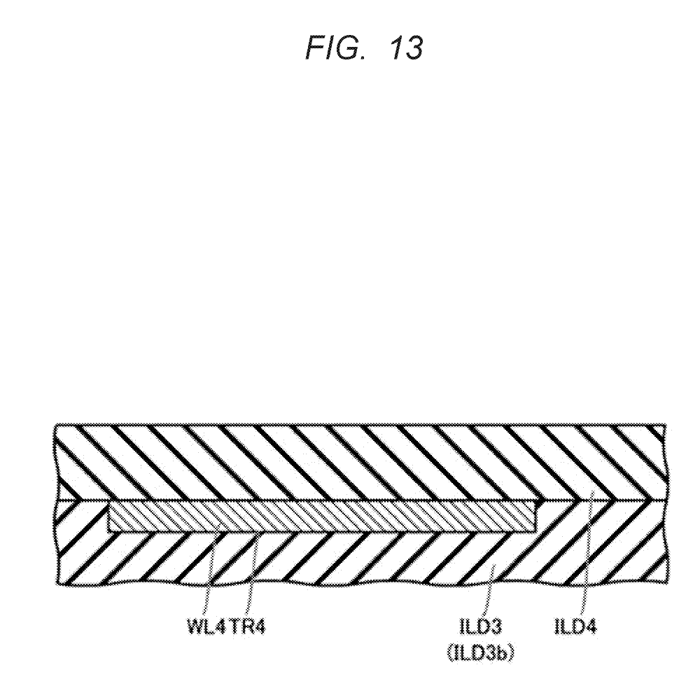

As shown in FIG. 12, in the preparation step S5, a semiconductor substrate with at least one interlayer insulating film ILD is prepared. If a plurality of interlayer insulating films ILD are formed at this stage, the top layer among the plurality of interlayer insulating films ILD is the interlayer insulating film ILD3. At this stage, the wiring WL4 is formed in the interlayer insulating film ILD3. As shown in FIG. 13, in the interlayer insulating film formation step S6, the interlayer insulating film ILD4 is formed on the interlayer insulating film ILD3 by, for example, the CVD method.

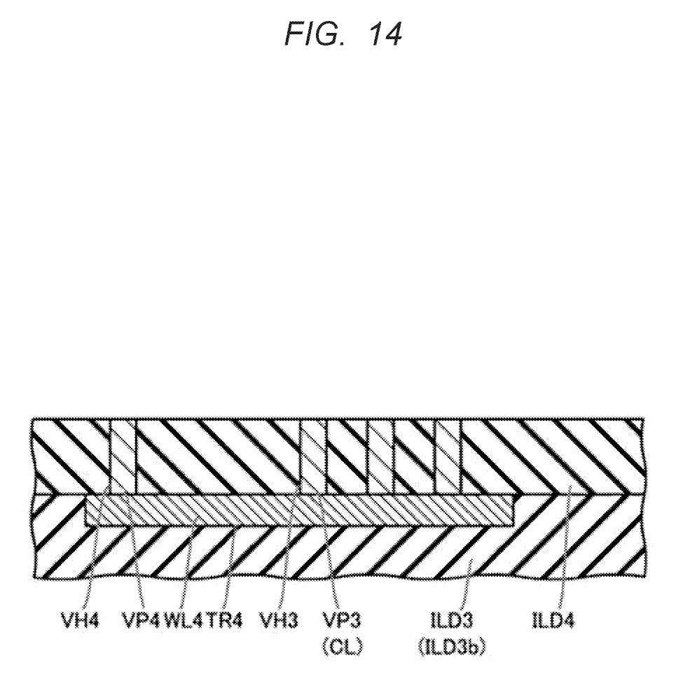

As shown in FIG. 14, in the via plug formation step S7, a plurality of via plugs VP3 are formed in the interlayer insulating film ILD4. Also, in the via plug formation step S7, the via plug VP4 is formed. In the via plug formation step S7, first, a resist pattern with openings is formed on the interlayer insulating film ILD4. Second, the via holes VH3, VH4 are formed by performing dry etching on the interlayer insulating film ILD4 through the openings of the resist pattern. Third, by, for example, the CVD method, the constituent materials such as via plugs VP3 are formed in the via holes VH3, VH4, and on the interlayer insulating film ILD4. Fourth, by, for example, the CMP method, the constituent materials such as via plugs VP3 formed outside the via holes VH3, VH4 are removed. Thus, the via plugs VP3, VP4 are formed.

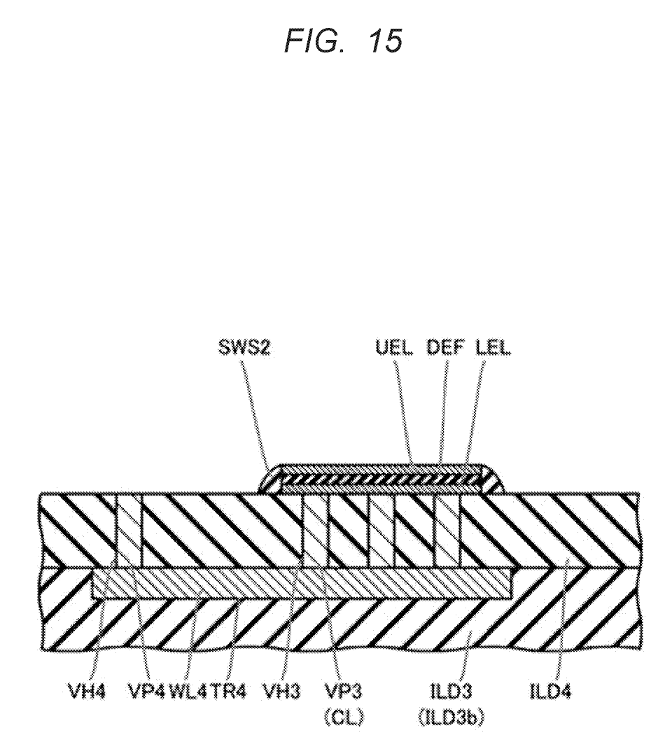

As shown in FIG. 15, in the capacitor formation step S8, the lower electrode LEL, the dielectric film DEF, the upper electrode UEL, and the sidewall spacer SWS2 are formed on the interlayer insulating film ILD4. In the capacitor formation step S8, first, the constituent materials of the lower electrode LEL, the dielectric film DEF, and the upper electrode UEL are sequentially formed on the interlayer insulating film ILD1. The constituent materials of the lower electrode LEL and the upper electrode UEL are formed by, for example, sputtering, and the constituent material of the dielectric film DEF is formed by, for example, the CVD method. Second, a resist pattern is formed on the constituent material of the upper electrode UEL. Third, dry etching is performed on the constituent materials of the lower electrode LEL, the dielectric film DEF, and the upper electrode UEL using the resist pattern as a mask.

Fifth, by, for example, the CVD method, the constituent material of the sidewall spacer SWS2 is formed on the interlayer insulating film ILD4 so as to cover the lower electrode LEL, the dielectric film DEF, and the upper electrode UEL. Sixth, etch-back is performed on the constituent material of the sidewall spacer SWS2. Thus, the lower electrode LEL, the dielectric film DEF, the upper electrode UEL, and the sidewall spacer SWS2 are formed.

In the wiring formation step S9, the wiring WL5 is formed so as to cover the sidewall spacer SWS2 and the upper electrode UEL. In the wiring formation step S9, first, by, for example, sputtering, the constituent materials of the barrier metal BM1, the wiring WL5, and the barrier metal BM2 are sequentially formed so as to cover the sidewall spacer SWS2 and the upper electrode UEL. Second, a resist pattern is formed on the constituent material of the barrier metal BM2. Third, dry etching is performed on the constituent materials of the barrier metal BM1, the wiring WL5, and the barrier metal BM2 using the resist pattern as a mask. Thus, the barrier metal BM1, the wiring WL5, the wiring WL6, and the barrier metal BM2 are formed, and the structure of the semiconductor device DEV3 shown in FIG. 10 is formed.

### Effects of Semiconductor Device DEV3

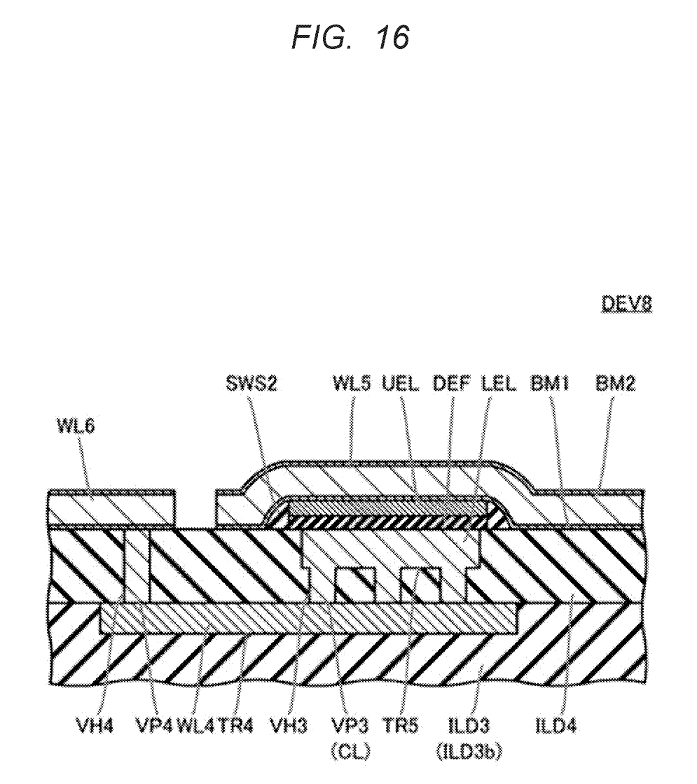

As shown in FIG. 16, in the semiconductor device DEV8 according to a comparative example, the trench TR5 is formed on the upper surface of the interlayer insulating film ILD4, and the via hole VH3 is formed on the bottom surface of the trench TR5. In the trench TR5, the lower electrode LEL is formed. In the manufacturing method of the semiconductor device DEV8, in the via plug formation step S7, a separate mask is required to form the trench TR5 in addition to the mask for forming the via holes VH3 and VH4. That is, according to the manufacturing method of the semiconductor device DEV8, the MIM capacitor formed of the lower electrode LEL, the dielectric film DEF, and the upper electrode UEL cannot be formed using a single mask.

On the other hand, in the semiconductor device DEV3, the constituent materials of the lower electrode LEL, the dielectric film DEF, and the upper electrode UEL are sequentially formed. Subsequently, by collectively patterning the constituent materials of the lower electrode LEL, the dielectric film DEF, and the upper electrode UEL, the lower electrode LEL, the dielectric film DEF, and the upper electrode UEL are formed. Therefore, according to the semiconductor device DEV3, the MIM capacitor can be formed using a single mask, that is, the mask for forming the resist pattern used in the capacitor formation step S8.

### Fourth Embodiment

The semiconductor device DEV4 according to the fourth embodiment will be described. Here, the differences from the semiconductor device DEV3 will be mainly described, and repetitive descriptions will not be repeated.

### Structure of Semiconductor Device DEV4

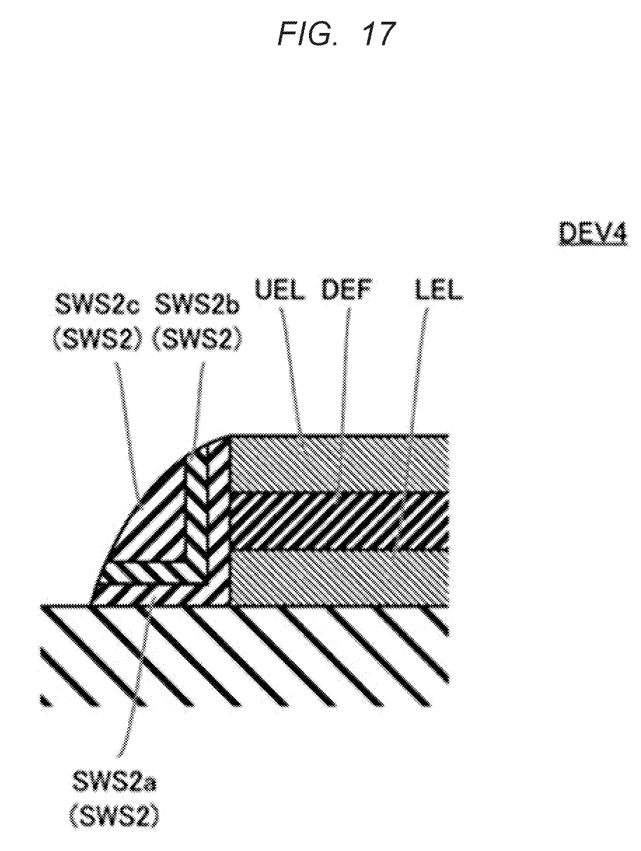

As shown in FIG. 17, in the semiconductor device DEV4, the sidewall spacer SWS2 includes a first layer SWS2a, a second layer SWS2b, and a third layer SWS2c. The second layer SWS2b is formed on the first layer SWS2a, and the third layer SWS2c is formed on the second layer SWS2b. The constituent material of the second layer SWS2b is different from the constituent materials of the first layer SWS2a and the third layer SWS2c. The first layer SWS2a and the third layer SWS2c are formed of, for example, silicon oxide. The second layer SWS2b is formed of, for example, silicon nitride.

In the manufacturing method of the semiconductor device DEV4, after the lower electrode LEL, the dielectric film DEF, and the upper electrode UEL are formed in the capacitor formation step S8, the constituent materials of the first layer SWS2a, the second layer SWS2b, and the third layer SWS2c are sequentially formed by, for example, the CVD method. Next, the etch-back for the constituent materials of the first layer SWS2a, the second layer SWS2b, and the third layer SWS2c is sequentially performed. As a result, the sidewall spacer SWS2 having the first layer SWS2a, the second layer SWS2b, and the third layer SWS2c is formed.

### Manufacturing Method of Semiconductor Device DEV4

### Effects of Semiconductor Device DEV4

In the semiconductor device DEV3, the etch-back for the constituent material of the sidewall spacer SWS2 is terminated when the exposure of via plugs VP3, VP4 is detected. However, since the area ratio of via plugs VP3, VP4 to the upper surface of the interlayer insulating film ILD4 is small, such detection is difficult. As a result, the upper surfaces of via plugs VP3, VP4 may become recessed due to excessive exposure to etching gas.

On the other hand, in the semiconductor device DEV4, the etch-back is temporarily stopped when the etch-back for the constituent materials of the third layer SWS2c and the second layer SWS2b is completed. Then, by performing a short etch-back for a predetermined time on the constituent material of the first layer SWS2a, the formation of the sidewall spacer SWS2 is completed. Therefore, it is not necessary to detect the exposure of via plugs VP3, VP4 to determine the timing of the end of the etch-back. Therefore, according to the semiconductor device DEV4, it is possible to suppress the recess of the upper surfaces of via plugs VP3, VP4 due to excessive exposure to etching gas.

### Fifth Embodiment

The semiconductor device DEV5 according to the fifth embodiment will be described. Here, the differences from the semiconductor device DEV3 will be mainly described, and redundant explanations will not be repeated.

### Structure of the Semiconductor Device DEV5

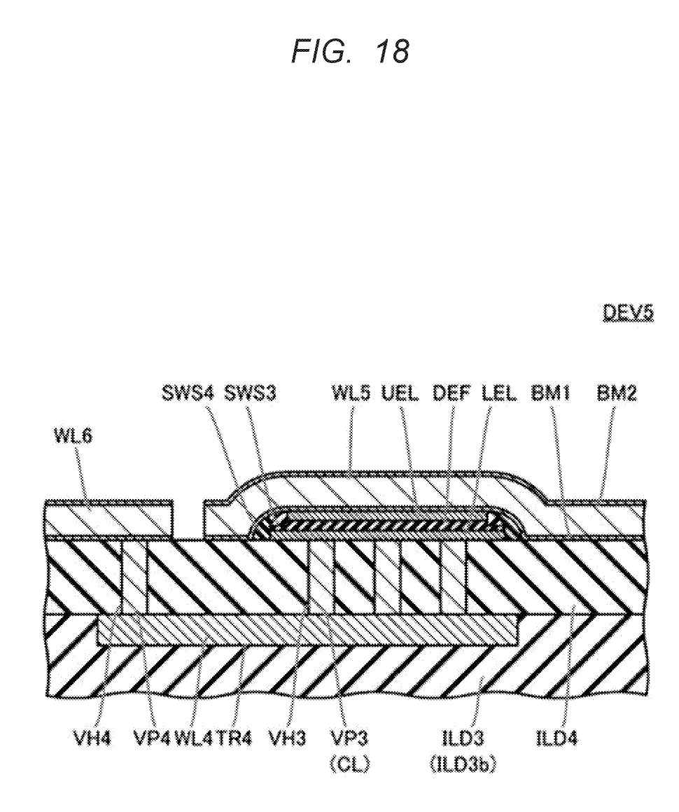

As shown in FIG. 18, the semiconductor device DEV5 does not have the sidewall spacer SWS2. In the semiconductor device DEV5, in cross-sectional view, the lower electrode LEL and the dielectric film DEF protrude from both side surfaces of the upper electrode UEL. The semiconductor device DEV5 has a sidewall spacer SWS3 and a sidewall spacer SWS4. The sidewall spacer SWS3 is formed on the dielectric film DEF so as to contact both side surfaces of the upper electrode UEL. The sidewall spacer SWS4 is formed on the interlayer insulating film ILD4 so as to cover the sidewall spacer SWS3 and to contact both side surfaces of the dielectric film DEF and the lower electrode LEL. That is, in the semiconductor device DEV4, the wiring WL5 and the lower electrode LEL are electrically insulated by the sidewall spacer SWS4. The sidewall spacers SWS3, SWS4 are formed of, for example, silicon oxide.

### Manufacturing Method of the Semiconductor Device DEV5

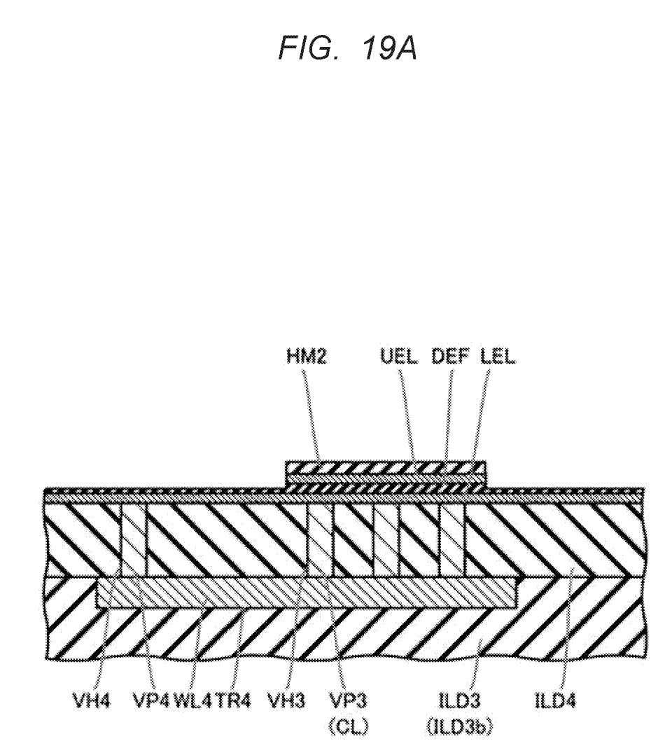

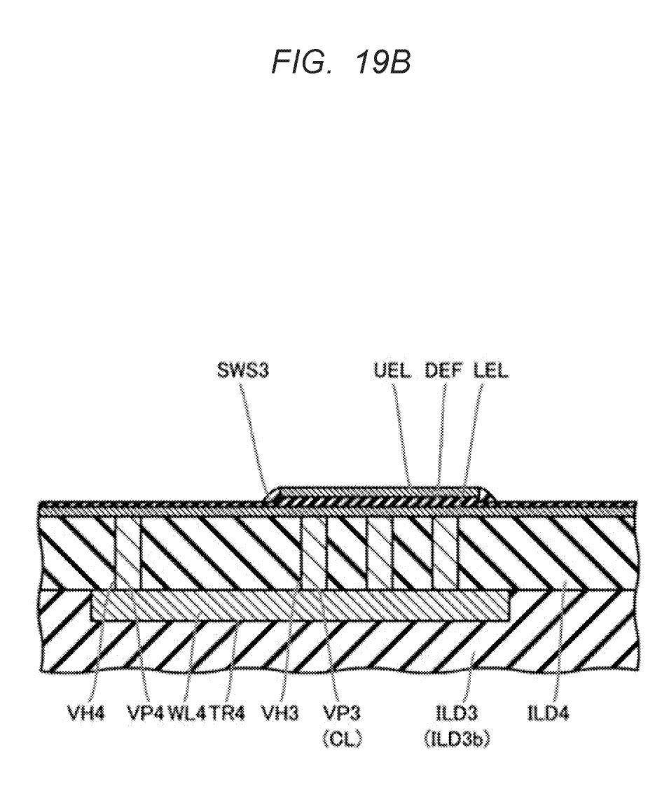

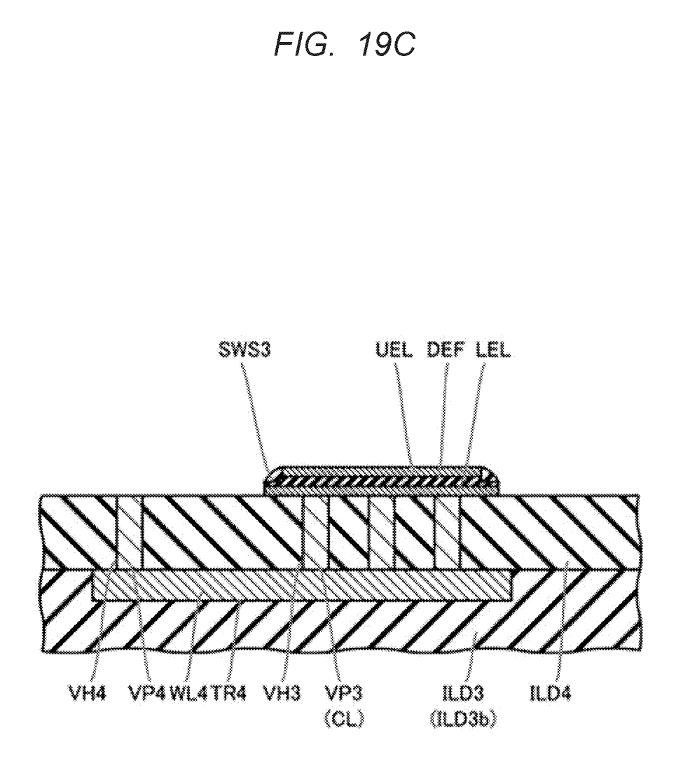

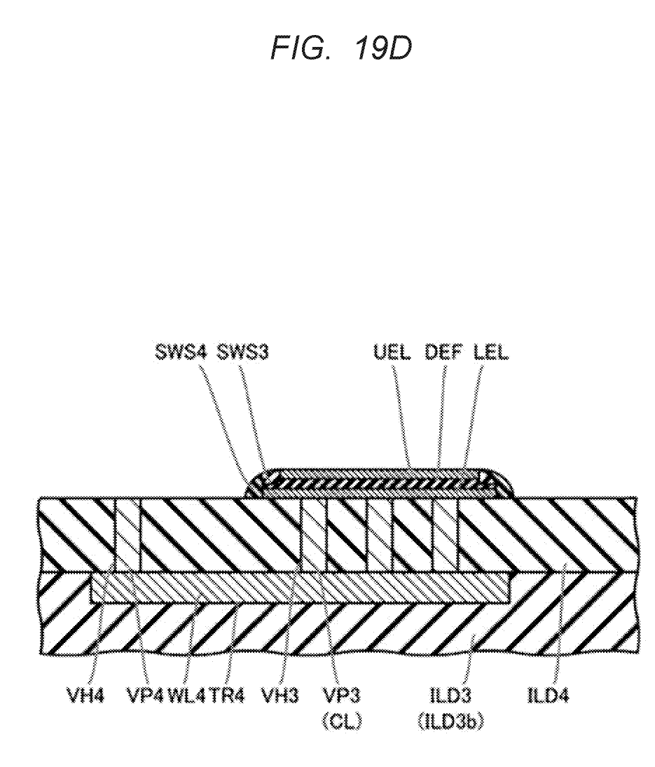

In the manufacturing method of the semiconductor device DEV5, the sidewall spacers SWS3, SWS4 are further formed in the capacitor formation step S8. As shown in FIG. 19A, in the capacitor formation step S2 of the manufacturing method of the semiconductor device DEV5, first, the constituent materials of the lower electrode LEL, the dielectric film DEF, and the upper electrode UEL are sequentially formed on the interlayer insulating film ILD4.

Second, for example, by the CVD method, the constituent material of the hard mask HM2 is formed on the constituent material of the upper electrode UEL. Third, a resist pattern is formed on the constituent material of the hard mask HM2. Fourth, by performing dry etching on the constituent material of the hard mask HM2 using the resist pattern as a mask, the hard mask HM2 is formed. Fifth, dry etching is performed on the constituent material of the upper electrode UEL using the hard mask as a mask.

As shown in FIG. 19B, in the capacitor formation step S8 of the manufacturing method of the semiconductor device DEV5, sixth, for example, by the CVD method, the constituent material of the sidewall spacer SWS3 is formed on the dielectric film DEF so as to cover the upper electrode UEL and the hard mask HM2. Seventh, etch-back is performed on the constituent material of the sidewall spacer SWS3. At this time, the hard mask HM2 is also removed. As a result, the sidewall spacer SWS3 is formed.

As shown in FIG. 19C, in the capacitor formation step S8 of the manufacturing method of the semiconductor device DEV5, eighth, dry etching is performed on the constituent materials of the dielectric film DEF and the lower electrode LEL using the sidewall spacer SWS3 as a mask. As a result, the lower electrode LEL, the dielectric film DEF, and the upper electrode UEL are formed. As shown in FIG. 19D, in the capacitor formation step S8 of the manufacturing method of the semiconductor device DEV5, ninth, after the constituent material of the sidewall spacer SWS4 is formed on the interlayer insulating film ILD4 so as to cover the sidewall spacer SWS3 and the upper electrode UEL, for example, by the CVD method, etch-back is performed on the constituent material of the sidewall spacer SWS4. As a result, the sidewall spacer SWS4 is formed.

In the semiconductor device DEV5, the dielectric film DEF protrudes from both side surfaces of the upper electrode UEL. Also, In the semiconductor device DEV5, the side surfaces of the dielectric film DEF are formed after the upper electrode UEL is formed. Therefore, In the semiconductor device DEV5, compared to the semiconductor device DEV3, the extended surface distance between the side surfaces of the lower electrode LEL and the upper electrode UEL is longer, making it difficult for the constituent material of the upper electrode UEL to adhere to the side surfaces of the dielectric film DEF. Thus, according to the semiconductor device DEV5, it is possible to suppress the flow of leakage current between the lower electrode LEL and the upper electrode UEL through the side surfaces of the dielectric film DEF. In addition, since a single mask is used in the capacitor formation step S8 in the manufacturing method of the semiconductor device DEV5, the manufacturing step of the MIM capacitor can be simplified.

### Sixth Embodiment

The semiconductor device DEV6 according to the sixth embodiment will be described. Here, the differences from the semiconductor device DEV3 will be mainly described, and redundant explanations will not be repeated.

### Structure of the Semiconductor Device DEV6

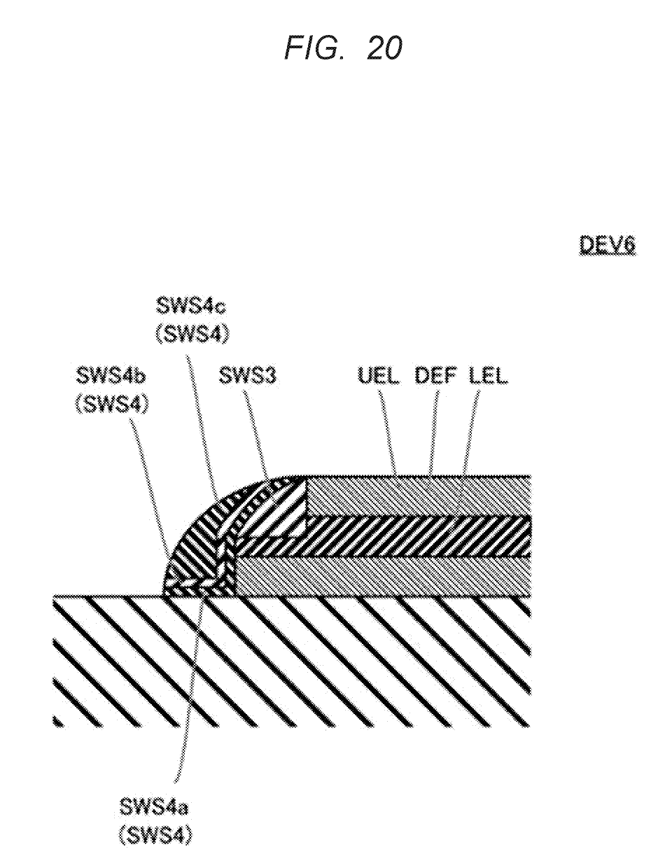

As shown in FIG. 20, in the semiconductor device DEV6, the sidewall spacer SWS4 has a fourth layer SWS4a, a fifth layer SWS4b, and a sixth layer SWS4c. The fifth layer SWS4b is formed on the fourth layer SWS4a, and the sixth layer SWS4c is formed on the fifth layer SWS4b. The constituent material of the fifth layer SWS4b is different from the constituent materials of the fourth layer SWS4a and the sixth layer SWS4c. The fourth layer SWS4a and the sixth layer SWS4c are formed of, for example, silicon oxide. The fifth layer SWS4b is formed of, for example, silicon nitride.

### Manufacturing Method of the Semiconductor Device DEV6

In the manufacturing method of the semiconductor device DEV6, in the capacitor formation step S8, for example, by the CVD method, after the lower electrode LEL, the dielectric film DEF, the upper electrode UEL, and the sidewall spacer SWS3 are formed, the constituent materials of the fourth layer SWS4a, the fifth layer SWS4b, and the sixth layer SWS4c are sequentially formed. Next, etch-back is sequentially performed on the constituent materials of the fourth layer SWS4a, the fifth layer SWS4b, and the sixth layer SWS4c. As a result, the sidewall spacer SWS4 having the fourth layer SWS4a, the fifth layer SWS4b, and the sixth layer SWS4c is formed.

### Effects of Semiconductor Device DEV6

In the semiconductor device DEV5, the etch-back for the constituent material of the sidewall spacer SWS4 is terminated when the exposure of via plugs VP3, VP4 is detected. However, since the area ratio of via plugs VP3, VP4 to the upper surface of the interlayer insulating film ILD4 is small, such detection is difficult. As a result, the upper surfaces of via plugs VP3, VP4 may become recessed due to excessive exposure to etching gas.

On the other hand, in the semiconductor device DEV6, the etch-back is temporarily stopped when the etch-back for the constituent materials of the sixth layer SWS4c and the fifth layer SWS4b is completed. Then, by performing a short etch-back for a predetermined time on the constituent material of the fourth layer SWS4a, the formation of the sidewall spacer SWS4 is completed. Therefore, it is not necessary to detect the exposure of via plugs VP3, VP4 to determine the timing of the end of the etch-back. Therefore, according to the semiconductor device DEV6, it is possible to suppress the recess of the upper surfaces of via plugs VP3, VP4 due to excessive exposure to etching gas.

Although the invention made by the inventor has been specifically described based on the embodiment, the present invention is not limited to the above embodiment, and it is needless to say that various modifications can be made without departing from the gist thereof.

What is claimed is:

1. A semiconductor device comprising:
a first interlayer insulating film;
a lower electrode formed on the first interlayer insulating film;
a dielectric film formed on the lower electrode;
an upper electrode formed on the dielectric film; and
at least one conductive layer formed in the first interlayer insulating film so as to contact the lower electrode.

2. The semiconductor device according to claim 1,
wherein at least one first trench is formed at an upper surface of the first interlayer insulating film
wherein the at least one conductive layer is at least one first wiring, and
wherein the at least one first wiring is formed in the at least one first trench.

3. The semiconductor device according to claim 2,
wherein the at least one first trench comprises a plurality of first trenches,
wherein the at least one first wiring comprises a plurality of first wirings,
wherein the plurality of first wirings are arranged in a first direction with a distance between two of the plurality of first wirings adjacent to each other in plan view, and
wherein each of the plurality of first wirings extends in a second direction perpendicular to the first direction in plan view.

4. The semiconductor device according to claim 2, comprising:
a first sidewall spacer,
wherein the dielectric film protrudes from both side surfaces of the upper electrode in cross-sectional view, and
wherein the first sidewall spacer is formed on the dielectric film so as to contact the both side surfaces of the upper electrode.

5. The semiconductor device according to claim 4, comprising:
a hard mask formed on the upper electrode.

6. The semiconductor device according to claim 4, comprising:
a second interlayer insulating film formed on the first interlayer insulating film so as to cover the lower electrode, the dielectric film, and the upper electrode;
a second wiring and a third wiring; and
a first via plug and a second via plug,
wherein a second trench and a third trench are formed at an upper surface of the second interlayer insulating film,
wherein a first via hole is formed at a bottom surface of the second trench so as to reach an upper surface of the at least one first wiring,
wherein a second via hole is formed at a bottom surface of the third trench so as to reach an upper surface of the upper electrode,
wherein the second wiring is formed in the second trench,
wherein the third wiring is formed in the third trench,
wherein the first via plug is formed in the first via hole and electrically connects the second wiring and the at least one first wiring, and
wherein the second via plug is formed in the second via hole and electrically connects the third wiring and the upper electrode.

7. The semiconductor device according to claim 6,
wherein the at least one first wiring, the second wiring, the third wiring, the first via plug, and the second via plug are formed of copper or copper alloy.

8. The semiconductor device according to claim 1, comprising:
a plurality of interlayer insulating films,
wherein the first interlayer insulating film is located as a top layer among the plurality of interlayer insulating films.

9. The semiconductor device according to claim 8,
wherein at least one third via hole is formed in the first interlayer insulating film,
wherein the at least one conductive layer is at least one third via plug, and
wherein the at least one third via plug is formed in the at least one third via hole.

10. The semiconductor device according to claim 9,
wherein the at least one third via plug is formed of tungsten.

11. The semiconductor device according to claim 8, comprising:
a second sidewall spacer; and
a fourth wiring,
wherein the second sidewall spacer is formed on the first interlayer insulating film so as to contact both side surfaces of each of the lower electrode, the dielectric film, and the upper electrode in cross-sectional view, and
wherein the fourth wiring is formed on the first interlayer insulating film so as to cover the upper electrode and the second sidewall spacer.

12. The semiconductor device according to claim 11,
wherein the second sidewall spacer comprises:
a first layer;
a second layer formed on the first layer; and
a third layer formed on the second layer, and
wherein the second layer is formed of a material different from the first layer and the third layer.

13. The semiconductor device according to claim 12,
wherein the first layer and the third layer are formed of silicon oxide, and
wherein the second layer is formed of silicon nitride.

14. The semiconductor device according to claim 11,
wherein the fourth wiring is formed of aluminum or aluminum alloy.

15. The semiconductor device according to claim 8, comprising:
a third sidewall spacer and a fourth sidewall spacer; and
a fifth wiring,
wherein the dielectric film protrudes from both side surfaces of the upper electrode in cross-sectional view,
wherein the third sidewall spacer is formed on the dielectric film so as to contact the both side surfaces of the upper electrode in cross-sectional view, and
wherein the fourth sidewall spacer is formed on the first interlayer insulating film so as to contact both side surfaces of each of the dielectric film and the lower electrode and to cover the third sidewall spacer in cross-sectional view, and
wherein the fifth wiring is formed on the first interlayer insulating film so as to cover the upper electrode and the fourth sidewall spacer.

16. The semiconductor device according to claim 15,
wherein the fourth sidewall spacer comprises:
a fourth layer;
a fifth layer formed on the fourth layer; and
a sixth layer formed on the fifth layer, and
wherein the fifth layer is formed of a material different from the fourth layer and the sixth layer.

17. The semiconductor device according to claim 16,
wherein the fourth layer and the sixth layer are formed of silicon oxide, and
wherein the fifth layer is formed of silicon nitride.

18. The semiconductor device according to claim 15,
wherein the fifth wiring is formed of aluminum or aluminum alloy.

19. The semiconductor device according to claim 3,
wherein the lower electrode overlaps the plurality of first wirings in plan view.
